(19) United States
(12) Patent Application Publication
(10) Pub. No.: US 2014/0174352 A1
(43) Pub. Date: Jun. 26, 2014

(54) APPARATUS FOR PROCESSING WAFERS

(71) Applicants: Yong-Kyu JOO, Hwaseong-si (KR); Sang-Jun NOH, Hwaseong-si (KR); Nam-Kyu KIM, Yongin-si (KR); Dae-Ok KIM, Yongin-si (KR)

(72) Inventors: Yong-Kyu JOO, Hwaseong-si (KR); Sang-Jun NOH, Hwaseong-si (KR); Nam-Kyu KIM, Yongin-si (KR); Dae-Ok KIM, Yongin-si (KR)

(21) Appl. No.: 14/048,303

(22) Filed: Oct. 8, 2013

(30) Foreign Application Priority Data
Dec. 21, 2012 (KR) 10-2012-0150387

(51) Int. Cl. C23C 16/455

(52) U.S. Cl. CPC C23C 16/45563
USPC 118/715

(57) ABSTRACT

A wafer processing apparatus includes a first tube extending in a vertical direction, a second tube arranged in the first tube and defining a reaction chamber, the reaction chamber being configured to receive a boat that holds a plurality of wafers, first and second gas nozzles in the second tube, the first and second gas nozzles being configured to supply first and second reaction gases, respectively, and being spaced apart from each other along a circumferential direction of the second tube to define a central angle of at about 50° to about 130° with respect to a center of the second tube, and an exhaust portion configured to exhaust residual gas from the reaction chamber, the exhaust portion including an exhaust slit in the second tube and an exhaust space between the first tube and the second tube.

### CROSS-REFERENCE TO RELATED APPLICATION

The present application claims priority under 35 U.S.C. §119 to Korean Patent Application No. 10-2012-0150387, filed on Dec. 21, 2012, in the Korean Intellectual Property Office, and entitled: “Apparatus For Processing Wafers and Method of Processing Wafers,” which is incorporated by reference herein in its entirety.

### BACKGROUND

1. Field

Example embodiments relate to a wafer processing apparatus and a wafer processing method. More particularly, example embodiments relate to a wafer processing apparatus for depositing a layer on wafers and a wafer processing method using the same.

2. Description of the Related Art

A titanium nitride (TiN) layer may be used as a barrier layer or as an electrode of a transistor due to its low resistance, diffusion barrier properties, etc. For example, a plurality of vertically stacked wafers may be loaded into a batch reactor, and then an atomic layer deposition (ALD) process may be performed to form a layer, e.g., a titanium nitride (TiN) layer, on the wafers.

### SUMMARY

Example embodiments provide a wafer processing apparatus including a batch reactor and capable of optimizing times for maintenance.

Example embodiments provide a method of processing a wafer using the wafer processing apparatus.

According to example embodiments, a wafer processing apparatus includes a first tube extending in a vertical direction, a second tube arranged in the first tube and defining a reaction chamber, the reaction chamber being configured to receive a boat that holds a plurality of wafers, first and second gas nozzles in the second tube, the first and second gas nozzles being configured to supply first and second reaction gases, respectively, and being spaced apart from each other along a circumferential direction of the second tube to define a central angle of at about 50° to about 130° with respect to a center of the second tube, and an exhaust portion configured to exhaust residual gas from the reaction chamber, the exhaust portion including an exhaust slit in the second tube and an exhaust space between the first tube and the second tube.

The first and second gas nozzles may extend along a longitudinal direction of the second tube.

The first gas nozzle may have a plurality of ejection holes along a longitudinal direction thereof, and the second gas nozzle may have a plurality of ejection holes along a longitudinal direction thereof.

The boat may be between the first gas nozzle and the exhaust slit, the exhaust slit being opposite to the first gas nozzle.

The first gas nozzle and the second gas nozzle may define a central angle of about 60° with respect to the center of the second tube.

The first gas nozzle and the second gas nozzle may define a central angle of about 120° with respect to the center of the second tube.

The exhaust slit may be in a sidewall of the second tube, the exhaust slit extending in a longitudinal direction of the second tube.

The exhaust portion may further include an exhaust port connected to the exhaust space, the exhaust space being between an inner surface of the first tube and an outer surface of the second tube.

In plan view, a line passing through the center of the second tube from a position of the exhaust port and a line passing through the center of the second tube from a position of the exhaust slit may be substantially perpendicular to each other.

The first reaction gas may include a titanium precursor and the second reaction gas includes a nitrogen precursor.

The wafer processing apparatus may further include at least a third gas nozzle configured to clean the reaction chamber.

The third gas nozzle may include a first sub-nozzle configured to supply a cleaning gas and a second sub-nozzle configured to supply a purge gas.

The cleaning gas may include NF₃ gas and the purge gas may include NH₃ gas.

The boat may be supported rotatably in the second tube.

According to example embodiments, a method of processing a wafer includes providing a first tube extending in a vertical direction, arranging a second tube in the first tube to define a reaction chamber, loading a boat that holds a plurality of wafers into the reaction chamber, supplying first and second reaction gases toward the wafers from first and second gas nozzles in the second tube, respectively, such that a layer is formed on the wafers, the first and second gas nozzles being spaced apart from each other in along a circumferential direction of the second tube to define a central angle of at about 50° to about 130° with respect to a center of the second tube, and exhausting a residual gas from the reaction chamber, the residual gas existing the reaction chamber through an exhaust slit in the second tube and through an exhaust space between the first tube and the second tube.

The first reaction gas may include a titanium precursor and the second reaction gas includes a nitrogen precursor, such that an atomic layer deposition (ALD) process is performed on the wafers.

The method may further include supplying a cleaning gas and a purge gas into the reaction chamber to perform an in situ cleaning process.

Performing the in situ cleaning process may include supplying the cleaning gas to clean the second tube, and supplying the purge gas to remove an unreacted gas from the second tube.

The cleaning gas may include NF₃ gas and the purge gas may include NH₃ gas.

Supplying the purge gas may include maintaining the reaction chamber at a temperature of about 300° C. to about 500° C.

According to example embodiments, a wafer processing apparatus includes a first tube extending in a vertical direction, a second tube inside the first tube and defining a reaction chamber, first and second gas nozzles along inner sidewalls of the second tube, the first and second gas nozzles being configured to supply first and second reaction gases, respectively, toward stacked wafers in a center of the second tube, and the first and second gas nozzles being on the circumference of the second tube and spaced apart from each other along the circumference of the second tube to define a central angle of about 50° to about 130° with respect to a center of the second tube, and an exhaust portion including an exhaust slit in the second tube and an exhaust space between the first tube and the second tube, the exhaust slit and the exhaust space being in fluid communication.

The first and second gas nozzles may be rod-shaped tubes along a longitudinal direction of the second tube.

Each of the first and second gas nozzles may include a plurality of ejection holes spaced apart from each other along the longitudinal direction of the second tube, the ejection holes facing the center of the second tube.

The first and second gas nozzles may extend to overlap all the stacked wafers in the center of the second tube.

The first and second gas nozzles may be not in fluid communication, the first and second gas nozzles being configured to supply different gases.

### BRIEF DESCRIPTION OF THE DRAWINGS

Example embodiments will be more clearly understood from the following detailed description taken in conjunction with the accompanying drawings. FIGS. 1 through 6 represent non-limiting, example embodiments as described herein.

FIG. 1 illustrates a cross-sectional view of a wafer processing apparatus in accordance with example embodiments.

FIG. 2 illustrates a perspective view of a first tube of the wafer processing apparatus in FIG. 1.

FIG. 3 illustrates a perspective view of a second tube of the wafer processing apparatus in FIG. 1.

FIG. 4 illustrates a cross-sectional view taken along the line A-A′ in FIG. 3.

FIG. 5 illustrates a cross-sectional view of a first gas nozzle and a second gas nozzle of a wafer processing apparatus in accordance with example embodiments.

FIG. 6 illustrates a flow chart of a method of processing a wafer in accordance with example embodiments.

### DETAILED DESCRIPTION

Various example embodiments will be described more fully hereinafter with reference to the accompanying drawings, in which example embodiments are shown. Example embodiments may, however, be embodied in many different forms and should not be construed as limited to example embodiments set forth herein. Rather, these example embodiments are provided so that this disclosure will be thorough and complete, and will fully convey the scope of embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

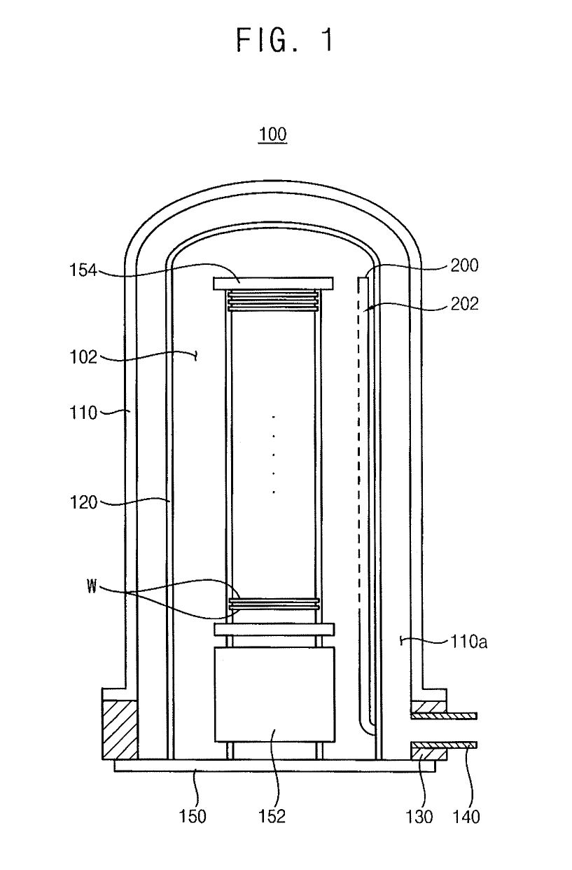

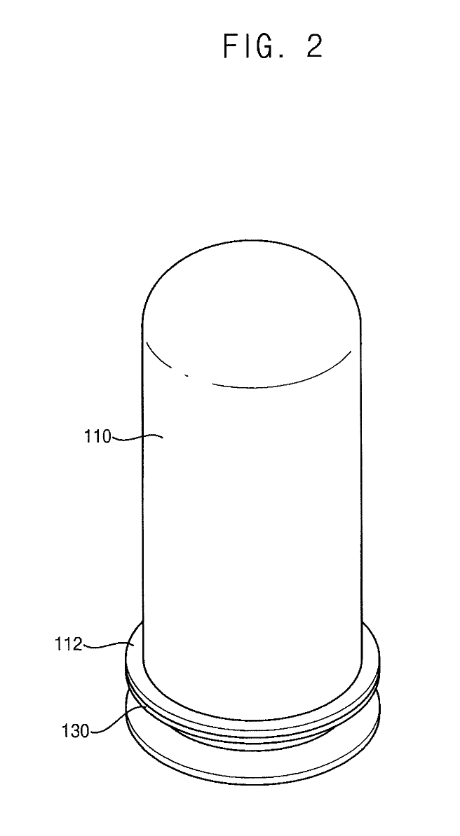

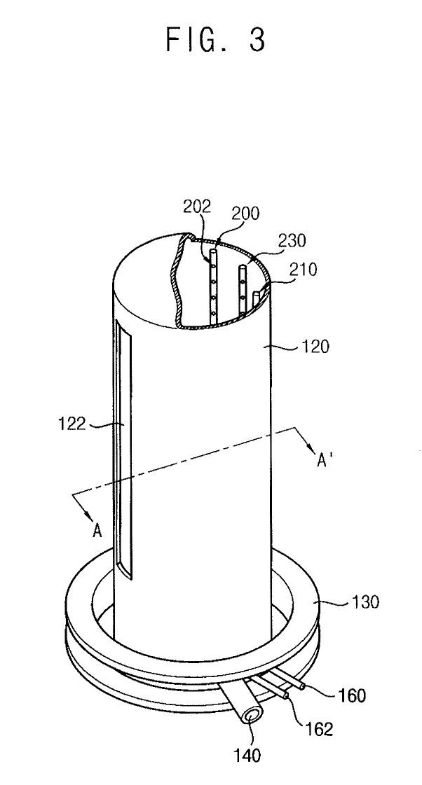

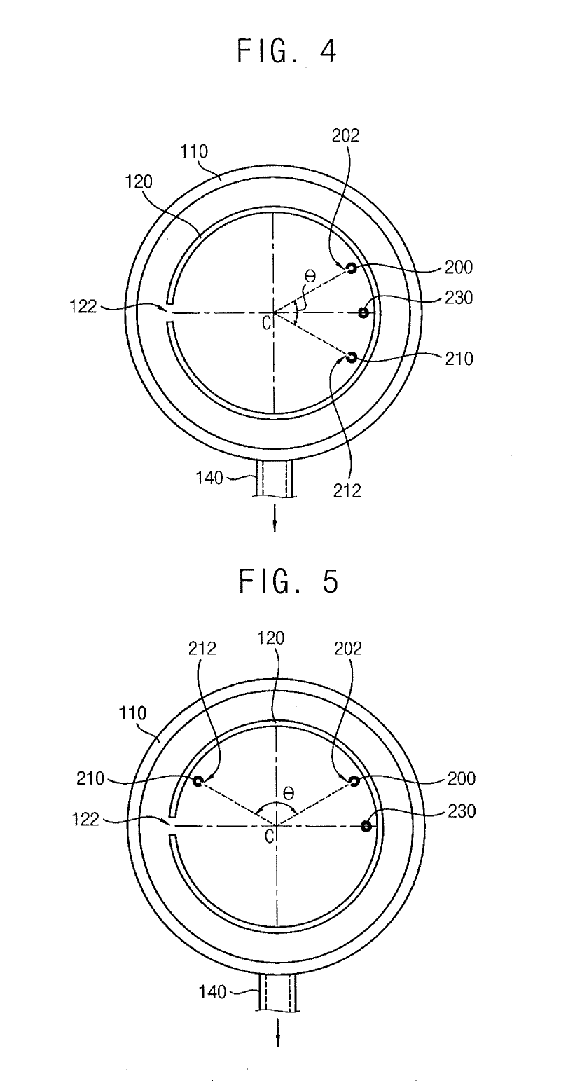

FIG. 1 illustrates a cross-sectional view of a wafer processing apparatus in accordance with example embodiments. FIG. 2 illustrates a perspective view of a first tube of the wafer processing apparatus in FIG. 1. FIG. 3 illustrates a perspective view of a second tube of the wafer processing apparatus in FIG. 1. FIG. 4 illustrates a cross-sectional view taken along the line A-A′ in FIG. 3.

Referring to FIGS. 1 to 4, a wafer processing apparatus 100 may include a first tube 110 extending in a vertical direction, a second tube 120 arranged in the first tube 110 to define a reaction chamber 102, first and second gas nozzles 200 and 210 arranged in the second tube 120 and spaced apart from each other in a circumferential direction of the second tube 120, and an exhaust portion for exhausting gas from the reaction chamber 102.

In example embodiments, the wafer processing apparatus 100 may include a vertical batch reactor. In particular, the second tube 120 may be arranged in the vertically extending first tube 110 to define a reactor that extends in the vertical direction. In other words, as can be seen in FIG. 1, longitudinal directions of both the first and second tubes 110 and 120 may be parallel to each other and may extend along a normal to a surface supporting the first and second tubes 110 and 120. Therefore, a vertical batch reactor having a longitudinal direction parallel to those of the first and second tubes 110 and 120 may be defined inside the second tube 120. The vertical batch reactor may receive a boat 154 that holds a plurality of wafers therein. The batch reactor may exhibit efficient heating and loading sequences.

Referring to FIG. 2, a lower portion of the first tube 110, i.e., an outer tube, may include an open end, and an upper portion of the first tube 110 may include a closed end. The lower open end of first tube 110 may have a flange 112 that protrudes in a radial direction. The flange 112 may be installed in a support 130. For example, the flange 112 of the first tube 110 may be connected to the support 130 by a sealing member, e.g., an O-ring, to seal the first tube 110. Accordingly, the first tube 110 may extend in the vertical direction from the support 130.

Referring back to FIG. 1, the second tube 120 may be an inner tube that is disposed inside the first tube 110. A lower portion of the second tube 120 may include an open end, and an upper portion of the second tube 120 may include a closed end. The second tube 120 may extend in the vertical direction, and may include the reaction chamber 102 of the reactor. The reaction chamber 102 may receive the boat 154 that holds a plurality of the wafers W, so the wafers W may be spaced apart from each other in the vertical direction. The boat 154 may be disposed on a stage 152 that is supported on a door plate 150. For example, at least twenty-five (25) to hundred-fifty (150) wafers W may be stacked in the boat 154.

The reaction chamber 102 may be maintained at a desired temperature by a temperature control system, e.g., a heater (not illustrated), that surrounds the first tube 110. Additionally, the boat 154 on the stage 152 may be supported rotatably in the second tube 120. Accordingly, while the boat 154 is rotated at a desired speed, reaction gases may be introduced to the wafers W to process a deposition process.

In example embodiments, as illustrated in FIG. 3, at least two gas nozzles may be provided in the second tube 120 to supply a reaction gas onto the wafers W. For example, the first gas nozzle 200 and the second gas nozzle 210 may be arranged in the second tube 120 to be spaced apart from each other in the circumferential direction of the second tube 120. The first and second gas nozzles 200 and 210 may form a central angle (θ) of at about 50° to about 130° with a vertex located at a center (C) of the second tube 120. In other words, as illustrated in FIG. 4, a first imaginary surface, i.e., between the center C of the second tube 120 and the first gas nozzle 200, and a second imaginary surface, i.e., between the center C of the second tube 120 and the second gas nozzle 210, define the angle (θ) therebetween.

For example, each of the first and second gas nozzles 200 and 210 may have a rod shape extending in the vertical direction of the second tube 120, e.g., as illustrated in FIGS. 1 and 3. The first and second gas nozzles 200 and 210 may be arranged adjacent to an inner surface of the second tube 120. For example, vertical recesses may be formed in the inner surface of the second tube 120 to extend in the vertical direction. The first and second gas nozzles 200 and 210 may be arranged along the vertical recesses, respectively. As illustrated in FIG. 4, a plurality of ejection holes 202 and 212 may be formed through, e.g., along the extending direction of, each of the first and second gas nozzles 200 and 210.

For example, the first and second gas nozzles 200 and 210 may have a diameter of about 1 mm to about 3 mm. As illustrated in FIG. 3, the ejection holes 202 and 212 may be spaced apart from one another by a predetermined distance along the extending direction of each of the first and second gas nozzles 200 and 210. It will be appreciated that the diameters of the gas nozzle and the ejection hole, and the distance between the ejection holes may be preferably chosen based on a material of a layer to be deposited, a recipe of the deposition process, etc.

A first reaction gas may be ejected towards the center (C) of the second tube 120 horizontally from the ejection holes 202 of the first gas nozzle 200. A second reaction gas may be ejected towards the center (C) of the second tube 120 horizontally from the ejection holes 212. It is noted that the center (C) of the second tube 120 refers to a major axis of the second tube 120 extending along a normal to a surface supporting the second tube 120, so each ejection hole 202 of the plurality of ejection holes 202 along the first gas nozzle 200 and each ejection hole 212 of the plurality of ejection holes 212 along the second gas nozzle 210 ejects, e.g., sprays, gas toward the center (C) of the second tube 120 along a radial direction with respect to the center (C) of the second tube 120.

In example embodiments, as illustrated in FIG. 3, an exhaust slit 122 may be formed in a sidewall of the second tube 120. The exhaust slit 122 may extend along the extending direction of the second tube 120. For example, the exhaust slit 122 may have a width of about 20 mm to about 30 mm. Gas from the reaction chamber 102 may be exhausted through the exhaust slit 122 to an exhaust space 110a between the first and second tubes 110 and 120.

In detail, the exhaust portion may exhaust gas from the reaction chamber 102 via the exhaust space 110a between the first tube 110 and the second tube 120. The exhaust portion may include an exhaust port 140 that is connected to the exhaust space 110a between an inner surface of the first tube 110 and an outer surface of the second tube 120. The exhaust port 140 may be formed to penetrate through the support 130, in which the flange 112 of the first tube 110 is installed. Accordingly, the gas in the reaction chamber 102 may flow out of the second tube 120 through the exhaust slit 122 into the exhaust space 110a between the first and second tubes 110 and 120 to be exhausted via the exhaust port 140.

For example, as illustrated in FIG. 4, the first and second gas nozzles 200 and 210 may form the central angle (θ), e.g., about 60°, with respect to the center (C) of the second tube 120. Hereinafter, an imaginary line extending from the exhaust port 140 and passing through the center (C) of the second tube 120 in plan view (dashed/dotted line in FIG. 4) will be referred to as a reference line. For example, when an angle between a first line, i.e., connecting the center (C) of the second tube 120 to the first gas nozzle 200 (dashed line in FIG. 4), and the reference line forms a central angle of about 60°, and when an angle between a second line, i.e., connecting the center (C) of the second tube 120 to the second gas nozzle 210 (dashed line in FIG. 4), and the reference line form a central angle of about 120°, a difference between the two central angles defines the central angle between the first and second lines. For example, the first gas nozzle 200 and the second gas nozzle 210 may be spaced apart from each other along the circumferential direction of the second tube 120, such that the first and second gas nozzles 200 and 210 may define a central angle (θ) of about 60° with respect to the center (C) of the second tube 120.

Additionally, when viewed in plan view, a line passing through the center (C) of the second tube 120 from the exhaust slit 122 is perpendicular to the reference line (dashed/dotted line in FIG. 4). That is, the line passing through the center (C) of the second tube 120 from the position of the exhaust port 140 and the line passing through the center (C) of the second tube 120 from the position of the exhaust slit define a central angle of about 90° with respect to the center (C) of the second tube 120.

Referring back to FIG. 3, the first gas nozzle 200 may be connected to a first gas supply port 160. The first gas supply port 160 may be formed to penetrate through the second tube 120. The first gas nozzle 200 may supply a first reaction gas including a titanium precursor into the reaction chamber 102. The second gas nozzle 210 may be connected to a second gas supply port 162. The second gas supply port 162 may be formed to penetrate through the second tube 120. The second gas nozzle 210 may supply a second reaction gas including a nitrogen precursor into the reaction chamber 102. For example, the first reaction gas may be TiCl₄ gas and the second reaction gas may be NH₃ gas. The TiCl₄ gas and the NH₃ gas may be supplied toward the plurality of the wafers W inside the reaction chamber 102 to deposit a layer, e.g., a TiN layer, on the wafer W.

The first and second reaction gases may be pulsed sequentially or simultaneously into the reaction chamber 102. Alternatively, one of the first and second reaction gases may be supplied at a predetermined flow rate and another of the first and second reaction gases may be pulsed into the reaction chamber 102. Additionally, a pulse gas or a cleaning gas may be supplied into the reaction chamber 102 through an additional gas nozzle (not illustrated) which is installed in the second tube 120. It will be understood that various methods for supplying the first and second reaction gases, the pulse gas, and the cleaning gas may be preferably chosen in order to deposit a titanium nitride layer having a uniform thickness and low resistance.

The reaction chamber 102 may be maintained at a temperature of about 300° C. to about 500° C., when the first and second reaction gases are supplied into the reaction chamber 102. For example, the reaction chamber 102 may be maintained at a temperature of about 380° C. Accordingly, a low-temperature atomic layer deposition (ALD) process may be performed to form a titanium nitride layer on each of the wafers W.

The gas in the reaction chamber 102 may be exhausted from the second tube 120 through the exhaust slit 122. The exhaust slit 122 may be formed in the second tube 120 to extend in the extending direction of the second tube 120. Accordingly, the first and second reaction gases may be ejected from the ejection holes 202 and 212 of the first and second gas nozzles 200 and 210, respectively, so the ejected gases may flow in the second tube 120 towards the vertically stacked wafers (W) in a horizontal direction perpendicular to the vertical direction (side flow). Then, the ejected reaction gases may be exhausted from the second tube 120 through the exhaust slit 122.

Then, the gas may flow through the exhaust space 110a between the inner surface of the first tube 110 and the outer surface of the second tube 120, to be exhausted via the exhaust port 140. Because the exhaust port 140 is installed in the lower portion of the first tube 110, the gas exhausted through the exhaust slit 122 may move downwardly into a lower portion of the exhaust space between the first tube 110 and the second tube 120, and then flow out of the exhaust port 140.

As mentioned above, the gases may flow in the reaction chamber 102 in the horizontal direction across the vertically stacked wafers (W), and then, may be exhausted from the second tube 120 through the exhaust slit 122. Then, the gases may move downwardly in the circumferential direction and the vertical direction along the outer surface of the second tube 120 within the first tube 110, and then, may flow through the exhaust space between the inner surface of the first tube 110 and the outer surface of the second tube 120, to be exhausted via the exhaust port 140.

In example embodiments, the wafer processing apparatus 100 may include a dual type batch reactor including the first tube 110 and the second tube 120, e.g., the first and second tubes 110 and 120 may be concentric as seen in FIG. 1. The wafer processing apparatus 100 may include the first gas nozzle 200 and the second gas nozzle 210 that are spaced apart from each other in the second tube 120 to form a predetermined central angle with respect to the center of the reaction chamber 102.

Accordingly, the gases ejected from the first and second gas nozzles 200 and 210 may flow in the reaction chamber 102 toward the vertically stacked wafers (W) in the horizontal, e.g., radial, direction perpendicular to the vertical direction, and then, may be exhausted from the reaction chamber 102 through the exhaust slit 122 of the second tube 120 that is formed to extend in the vertical direction. Therefore, a layer, e.g., a titanium nitride layer, having a uniform thickness may be formed on each of the wafers (W).

Further, because the first gas nozzle 200 for spraying TiCl₄ gas and the second gas nozzle 210 for spray NH₃ gas may be spaced apart from each other by a predetermined distance, a layer, e.g., a titanium nitride layer, may be prevented from being deposited excessively on any one of the gas nozzles to generate particles in the reaction chamber 102. Therefore, time for equipment repair and maintenance may be optimized.

In example embodiments, the wafer processing apparatus 100 may further include at least one nozzle 230 for cleaning the reaction chamber 102. The nozzle 230 may supply a cleaning gas and/or a purge gas. For example, the cleaning gas may include NF₃ gas, and the purge gas may include NH₃ gas. Although a single nozzle 230 is illustrated in FIG. 4, the wafer processing apparatus 100 may include a first nozzle for supplying the cleaning gas and a second nozzle for supplying the purge gas.

In detail, after a certain number of ALD processes are performed in the reaction chamber 102 of the wafer processing apparatus 100, an in-situ cleaning process may be performed to remove a layer deposited on, e.g., a sidewall of, the reaction chamber 102. That is, as the deposition processes are performed repeatedly in the reaction chamber 102, by-products may be deposited excessively on, e.g., a sidewall or bottom of, the reaction chamber 102 and peel off to generate particles in the reaction chamber 102. Accordingly, after performing a certain number of ALD processes, it may be determined whether or not a cleaning process for the reaction chamber 102 should be performed.

Whether or not to perform the cleaning process may be determined in consideration of the layer to be deposited, the reaction gas to be supplied, etc. For example, when a thickness of a titanium nitride layer deposited on the reaction chamber 102 is 1 μm or more, 1.5 μm or more, or 2 μm or more, a cleaning process may be performed. This cleaning process may be performed in the reaction chamber 102 without changing the state of the reaction chamber 102 where the deposition process was performed.

For example, first, NF₃ gas may be introduced from the nozzle 230 into the reaction chamber 102 to perform a cleaning process. At this time, the reaction chamber 102 may be maintained at a temperature of about 580° C. Then, NH₃ gas may be introduced into the reaction chamber 102, e.g., from a separate nozzle or a same nozzle as the NF₃ gas, to perform a purge process. At this time, the reaction chamber 102 may be maintained at a temperature of from about 400° C. to about 700° C., e.g., at a temperature of about 650° C. The purge process may be performed for about four (4) hours.

The in-situ cleaning process may include a purge process that uses NH₃ gas at a high temperature of about 650° C. Accordingly, after the in-situ cleaning process, deposition processes may be performed repeatedly to form a layer, e.g., a titanium nitride layer, having a uniform thickness on each of the wafers W. That is, the deposition processes may be performed until the layer, e.g., the titanium nitride layer, deposited on each of the wafers W in the reaction chamber 102 has a thickness of at least 1 μm. Therefore, time required for equipment repair and maintenance may be optimized, thereby increasing production rates.

FIG. 5 illustrates a cross-sectional view of a first gas nozzle and a second gas nozzle of a wafer processing apparatus in accordance with example embodiments. The wafer processing apparatus may be substantially the same as or similar to the apparatus described with reference to FIGS. 1 to 4, except for a different arrangement of the first and second gas nozzles along the circumference of the second tube 120. Thus, same reference numerals will be used to refer to the same or like elements as those described with reference to FIGS. 1 to 4, and any further repetitive explanation concerning the above elements will be omitted.

Referring to FIG. 5, the first gas nozzle 200 and the second gas nozzle 210 may form a central angle (θ) of about 120° with respect to the center (C) of the second tube 120. Hereinafter, an imaginary line passing through the center (C) of the second tube 120 from the position of an exhaust port 140 may be referred to as a reference line, when viewed in plan view. The first gas nozzle 200 may be arranged such that a first line passing through the center (C) of the second tube 120 from the position of the first gas nozzle 200 and the reference line may form a central angle of about 60°. The second gas nozzle 210 may be arranged such that a second line passing through the center (C) of the second tube 120 from the position of the second gas nozzle 210 and the reference line may form a central angle of about (−60°).

Alternatively, the second gas nozzle 210 may be arranged such that the second line passing through the center (C) of the second tube 120 from the position of the second gas nozzle 210 and the reference line may form a central angle of about 0°. In this case, the first gas nozzle 200 and the second gas nozzle 210 may form a central angle (θ) of about 60° with respect to the center (C) of the second tube 120.

When the first gas nozzle 200 is arranged such that the first gas nozzle 200 and the reference line form a central angle of about 60°, the second gas nozzle 210 may be spaced apart from the first gas nozzle 200 to form a central angle (θ) of at least about 50° with respect to the center (C) of the second tube 120.

For example, the first gas nozzle 200 may supply a first reaction gas into the reaction chamber 102 and the second gas nozzle 210 may supply a second reaction gas into the reaction chamber 102. The first reaction gas may be TiCl₄ gas, and the second reaction gas may be NH₃ gas. The TiCl₄ gas and the NH₃ gas may be supplied toward the plurality of the wafers to deposit a layer, e.g., a TiN layer, on the wafer.

The reaction chamber 102 may be maintained at a temperature of about 300° C. to about 500° C., when the first and second reaction gases are supplied into the reaction chamber 102. For example, the reaction chamber 102 may be maintained at a temperature of about 380° C. Accordingly, an ALD process may be performed to form, e.g., a titanium nitride layer, on the wafers W.

The first and second gas nozzles 200 and 210 may be spaced apart from each other in the circumferential direction of the second tube 120 to form a predetermined central angle (θ) with respect to the center (C) of the reaction chamber 102. Accordingly, a layer, e.g., a titanium nitride layer, may be prevented from being deposited excessively on any one of the gas nozzles to generate particles in the reaction chamber 102. Therefore, the time for equipment repair and maintenance may be optimized.

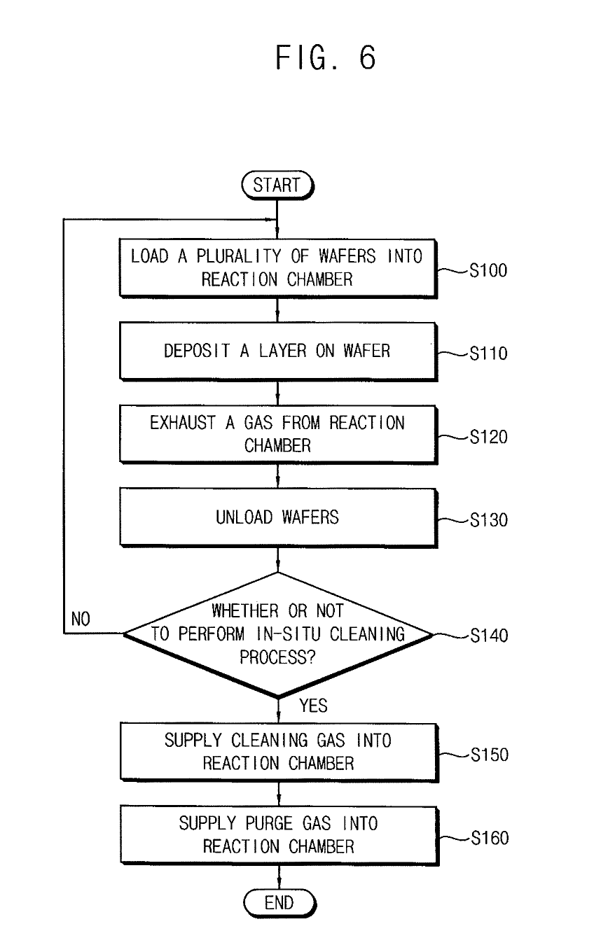

Hereinafter, a method of processing a plurality of wafers using the wafer processing apparatus in FIG. 1 will be described with reference to FIG. 6. FIG. 6 illustrates a flow chart of a method of processing a wafer in accordance with example embodiments. The method may be used to form, e.g., a titanium nitride layer, on a wafer. However, embodiments are not limited thereto.

Referring to FIGS. 1, 4, and 6, a plurality of wafers may be loaded into the reaction chamber 102 of the wafer processing apparatus 100 (S 100).

The first tube 110 of the wafer processing apparatus 100 may extend in the vertical direction, and the second tube 120 may be arranged inside the first tube 110 to define the reaction chamber 102. A stand-by chamber (not illustrated) may be disposed under the reaction chamber 102, and may be arranged in the vertical direction. After the wafers (W) are loaded into the boat 154, the boat 154 may be raised and loaded into the reaction chamber 102 by a driving unit (not illustrated). Then, first and second reaction gases may be supplied toward the wafers (W) through the first and second gas nozzles 200 and 210, respectively, to deposit a layer on the wafers (W) (S110).

The first and second gas nozzles 200 and 210 may be arranged in the second tube 120 to extend in the extending direction of the second tube 120. The first gas nozzle 200 may have a plurality of ejection holes 202 formed therein. The second gas nozzle 210 may have a plurality of ejection holes 212 formed therein. The ejection holes 202 and 212 may be formed along the extending direction of each of the first and second gas nozzles 200 and 210. The first and second gas nozzles 200 and 210 may be spaced apart from each other in a circumferential direction of the second tube 120 to form a central angle (θ) of about 50° to about 130° with respect to the center (C) of the second tube 120.

The first reaction gas may be ejected towards the center (C) of the second tube 120 via the ejection holes 202 of the first gas nozzle 200. The second reaction gas may be ejected towards the center (C) of the second tube 120 via the ejection holes 212. For example, the first reaction gas may be TiCl₄ gas, and the second reaction gas may be NH₃ gas. Additionally, a pulse gas or a cleaning gas may be supplied into the reaction chamber 102 through an additional gas nozzle (not illustrated). For example, the reaction chamber 102 may be maintained at a temperature of about 380° C. Accordingly, a low-temperature ALD process may be performed to form a titanium nitride layer on each of the wafers W.

Then, the gas may be exhausted from the reaction chamber 102 (S 120). The gas in the reaction chamber 102 may be exhausted from the second tube 120 through the exhaust slit 122 that is formed in a sidewall of the second tube 120 to extend in the extending direction of the second tube 120. Then, the gas exhausted through the exhaust slit 122 may move downwardly into a lower portion of an exhaust space 110a between the first tube 110 and the second tube 120, and then flow out of an exhaust port 140 that is installed in the support 130.

The first and second reaction gases may be ejected from the ejection holes 202 and 212 of the first and second gas nozzles 200 and 210, the ejected gases may flow in the second tube 120 toward the vertically stacked wafers (W) in a horizontal direction perpendicular to the vertical direction (side flow). Then, the gases may flow out of the reaction chamber 102 through the exhaust slit 122 of the second tube 120. Accordingly, a layer, e.g., a titanium nitride layer, having a uniform thickness may be formed on each of the wafers (W).

Further, because the first gas nozzle 200 for spraying TiCl₄ gas and the second gas nozzle 210 for spray NH₃ gas may be spaced apart from each other by a predetermined distance, a layer, e.g., a titanium nitride layer, may be prevented from being deposited excessively on any one of the gas nozzles to generate particles in the reaction chamber 102. Therefore, the time for equipment repair and maintenance may be optimized.

Furthermore, the gas exhausted through the exhaust slit 122 of the second tube 120 may move downwardly in the vertical direction between the first tube 110 and the second tube 120, and then flow out of the exhaust port 140. Accordingly, particles may be prevented from being generated due to gas lifting, thereby optimizing times for maintenance.

After forming the layer having a desired thickness on the wafers (W), the wafers (W) may be unloaded from the reaction chamber 102 (S 130).

After the deposition process, e.g., operations S100 to S130, is completed, it is determined whether or not to perform a cleaning process in the reaction chamber 102 (S 140). Whether or not to perform the cleaning process may be determined in consideration of the layer to be deposited, the reaction gas to be supplied, etc. When it is determined that the cleaning process is not required to be performed, the deposition process, e.g., operations S100 to S130, may be performed again. For example, when a thickness of the titanium nitride layer deposited on the wafers W in the reaction chamber 102 is about 1 μm or more, e.g., 1.5 μm, 2 μm or more, the cleaning process may be performed.

This cleaning process may be performed in the reaction chamber 102 without changing the state of the reaction chamber where the deposition process was performed. In particular, first, NF₃ gas may be introduced from the nozzle 230 into the reaction chamber 102 to perform a cleaning process (S150). At this time, the reaction chamber 102 may be maintained at a temperature of about 580° C. Then, NH₃ gas may be introduced into the reaction chamber 102 to perform a purge process (S 160). At this time, the reaction chamber 102 may be maintained at a temperature of about 400° C. to about 700° C., e.g., about 650° C. The purge process may be performed for about four (4) hours.

The in-situ cleaning process may include a purge process that uses NH₃ gas at the high temperature of 650° C. Accordingly, after the in-situ cleaning process, the deposition processes may be performed repeatedly to form a layer, e.g., a titanium nitride layer, having a uniform thickness on each of the wafers (W) until the titanium nitride layer deposited on the reaction chamber 102 has a thickness of at least 1 μm. Therefore, the time for equipment repair and maintenance may be optimized to thereby increase production rates.

In contrast, when a conventional deposition process is performed on a vertical stack of wafers in a conventional batch reactor, a thickness uniformity of a deposited layer across the wafers may be deteriorated. Further, if the deposition processes are performed repeatedly in the conventional batch reactor, layers may be deposited excessively on the reaction chamber to generate particles in the reaction chamber, to thereby reduce maintenance time.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A wafer processing apparatus, comprising:
a first tube extending in a vertical direction;
a second tube arranged in the first tube and defining a reaction chamber, the reaction chamber being configured to receive a boat that holds a plurality of wafers;
first and second gas nozzles in the second tube, the first and second gas nozzles being configured to supply first and second reaction gases, respectively, and being spaced apart from each other along a circumferential direction of the second tube to define a central angle of at about 50° to about 130° with respect to a center of the second tube; and
an exhaust portion configured to exhaust residual gas from the reaction chamber, the exhaust portion including an exhaust slit in the second tube and an exhaust space between the first tube and the second tube.

2. The wafer processing apparatus as claimed in claim 1, wherein the first and second gas nozzles extend along a longitudinal direction of the second tube.

3. The wafer processing apparatus as claimed in claim 2, wherein the first gas nozzle has a plurality of ejection holes along a longitudinal direction thereof, and the second gas nozzle has a plurality of ejection holes along a longitudinal direction thereof.

4. The wafer processing apparatus as claimed in claim 1, wherein the boat is between the first gas nozzle and the exhaust slit, the exhaust slit being opposite to the first gas nozzle.

5. The wafer processing apparatus as claimed in claim 4, wherein the first gas nozzle and the second gas nozzle define a central angle of about 60° with respect to the center of the second tube.

6. The wafer processing apparatus as claimed in claim 1, wherein the first gas nozzle and the second gas nozzle define a central angle of about 120° with respect to the center of the second tube.

7. The wafer processing apparatus as claimed in claim 1, wherein the exhaust slit is in a sidewall of the second tube, the exhaust slit extending in a longitudinal direction of the second tube.

8. The wafer processing apparatus as claimed in claim 1, wherein the exhaust portion further comprises an exhaust port connected to the exhaust space, the exhaust space being between an inner surface of the first tube and an outer surface of the second tube.

9. The wafer processing apparatus as claimed in claim 8, wherein, in plan view, a line passing through the center of the second tube from a position of the exhaust port and a line passing through the center of the second tube from a position of the exhaust slit are substantially perpendicular to each other.

10. The wafer processing apparatus as claimed in claim 1, wherein the first reaction gas includes a titanium precursor and the second reaction gas includes a nitrogen precursor.

11. The wafer processing apparatus as claimed in claim 1, further comprising at least a third gas nozzle configured to clean the reaction chamber.

12. The wafer processing apparatus as claimed in claim 11, wherein the third gas nozzle includes a first sub-nozzle configured to supply a cleaning gas and a second sub-nozzle configured to supply a purge gas.

13. The wafer processing apparatus as claimed in claim 12, wherein the cleaning gas includes NF₃ gas and the purge gas includes NH₃ gas.

14. The wafer processing apparatus as claimed in claim 1, wherein the boat is supported rotatably in the second tube.

15-20. (canceled)

21. A wafer processing apparatus, comprising:
a first tube extending in a vertical direction;
a second tube inside the first tube and defining a reaction chamber;
first and second gas nozzles along inner sidewalls of the second tube, the first and second gas nozzles being configured to supply first and second reaction gases, respectively, toward stacked wafers in a center of the second tube, and the first and second gas nozzles being on the circumference of the second tube and spaced apart from each other along the circumference of the second tube to define a central angle of about 50° to about 130° with respect to a center of the second tube; and
an exhaust portion including an exhaust slit in the second tube and an exhaust space between the first tube and the second tube, the exhaust slit and the exhaust space being in fluid communication.

22. The wafer processing apparatus as claimed in claim 21, wherein the first and second gas nozzles are rod-shaped tubes along a longitudinal direction of the second tube.

23. The wafer processing apparatus as claimed in claim 22, wherein each of the first and second gas nozzles includes a plurality of ejection holes spaced apart from each other along the longitudinal direction of the second tube, the ejection holes facing the center of the second tube.

24. The wafer processing apparatus as claimed in claim 22, wherein the first and second gas nozzles extend to overlap all the stacked wafers in the center of the second tube.

25. The wafer processing apparatus as claimed in claim 21, wherein the first and second gas nozzles are not in fluid communication, the first and second gas nozzles being configured to supply different gases.
